(19) United States
(12) Patent Application Publication
(10) Pub. No.: US 2019/0223325 A1
(43) Pub. Date: Jul. 18, 2019

(54) OPTICAL MODULE

(71) Applicant: InnoLight Technology (Suzhou) LTD., Suzhou (CN)

(72) Inventors: Chao ZHANG, Suzhou (CN); Kewu WANG, Suzhou (CN)

(73) Assignee: InnoLight Technology (Suzhou) LTD.

(21) Appl. No.: 16/250,106

(22) Filed: Jan. 17, 2019

(30) Foreign Application Priority Data
Jan. 18, 2018 (CN) 201810049924.9

(51) Int. Cl. H05K 7/20; H05K 1/18

(52) U.S. Cl. CPC H05K 7/20336; H05K 5/0052; H05K 2201/10121; H05K 1/181

(57) ABSTRACT

An optical module includes a housing, a printed circuit board disposed in the housing, a heat generating chip electrically connected to the printed circuit board, and a heat pipe disposed between the housing and the heat generating chip. The heat pipe has a heat absorbing end abutting the heat generating chip and a heat dissipating end away from the heat generating chip. The heat absorbing end absorbs heat generated from the heat generating chip and transfers the heat to the heat dissipating end. The heat dissipating end transfers the heat to an area of the housing that is away from the heat generating chip.

### CROSS-REFERENCE TO RELATED APPLICATION

This application is based upon and claims priority to Chinese Patent Application 201810049924.9, filed on Jan. 18, 2018, the entire content of which is incorporated herein by reference.

### FIELD OF THE DISCLOSURE

The present invention relates to the field of optical communication component manufacturing technology and, more particularly, to an optical module.

### BACKGROUND

With the rapid development of 4G communication and the growing demand for cloud computing, the market increasingly demands high-speed optical modules. In response to market demand for high-bandwidth and high-speed data transmission, module design has turned toward miniaturization and high density. Despite efforts to create highly integrated circuits that are smaller and consume less power, with the advancement of high-speed and high-bandwidth module technology, high thermal power consumption by the modules has become an issue that needs to be addressed. If good heat dissipation cannot be ensured, then the performance of temperature-sensitive chips and electricity-to-light and light-to-electricity converters in optical modules will decrease significantly and the entire module may fail to work properly or effectively. Therefore, a more efficient heat dissipation structure is needed to ensure stable operation of the devices.

### SUMMARY

An embodiment of the present disclosure provides an optical module including a housing, a printed circuit board disposed in the housing, a heat generating chip electrically connected to the printed circuit board, and a heat pipe disposed between the housing and the heat generating chip. The heat pipe has a heat absorbing end abutting the heat generating chip and a heat dissipating end away from the heat generating chip. The heat absorbing end absorbs heat generated from the heat generating chip and transfers the heat to the heat dissipating end. The heat dissipating end then transfers the heat to the area of the housing that is away from the heat generating chip.

### BRIEF DESCRIPTION OF THE DRAWINGS

FIG. 1 is a diagram illustrating a perspective view of an optical module in accordance with one embodiment of the present disclosure.

FIG. 2 is an enlarged view of area A in FIG. 1.

### DETAILED DESCRIPTION

The text below provides a detailed description of the present disclosure with reference to specific embodiments illustrated in the attached drawings. However, these embodiments do not limit the present disclosure; the scope of protection for the present disclosure covers changes made to the structure, method, or function by persons having ordinary skill in the art on the basis of these embodiments.

In order to facilitate the presentation of the drawings in the present disclosure, the sizes of certain structures or portions have been enlarged relative to other structures or portions. Therefore, the drawings in the present disclosure are only for the purpose of illustrating the basic structure of the subject matter of the present disclosure.

Additionally, terms in the text indicating relative spatial position, such as “upper,” “above,” “lower,” “below,” and so forth, are used for explanatory purposes in describing the relationship between a unit or feature depicted in a drawing with another unit or feature therein. Terms indicating relative spatial position may refer to positions other than those depicted in the drawings when a device is being used or operated. For example, if a device shown in a drawing is flipped over, a unit which is described as being located “below” or “under” another unit or feature will be located “above” the other unit or feature. Therefore, the illustrative term “below” may include positions both above and below. A device may be oriented in other ways (rotated 90 degrees or facing another direction), and descriptive terms that appear in the text and are related to space should be interpreted accordingly.

Moreover, it should be understood that although the terms “first,” “second,” etc. may be used in the text to describe various components or structures, the objects being described should not be limited by the aforementioned terms. The aforementioned terms are only for the purpose of differentiating between the objects being described. For example, a first surface may be referred to as a second surface, and, similarly, a second surface may also be referred to as a first surface. This does not deviate from the scope of protection for the present disclosure.

A purpose of the present disclosure is to provide an optical module that reduces an operating junction temperature of a heat generating chip and allows the temperature of a housing to be more uniform, thereby significantly increasing the service life of the optical module.

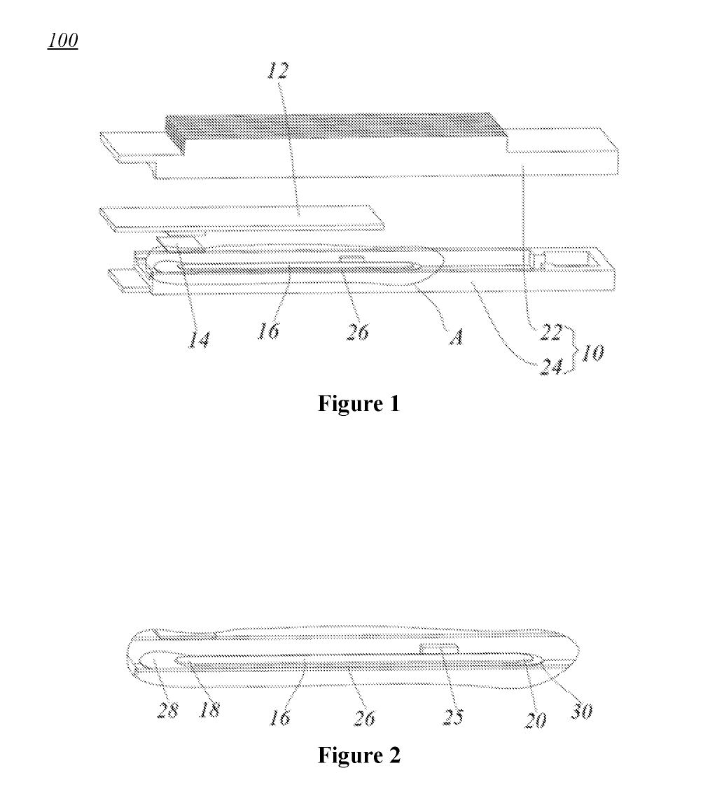

FIG. 1 is a diagram illustrating a perspective view of an optical module 100 according to an embodiment of the present disclosure. FIG. 2 is an enlarged view of area A in FIG. 1. As shown in FIG. 1 and FIG. 2, the optical module 100 includes a housing 10, a printed circuit board 12 disposed in the housing 10, and a heat generating chip 14 electrically connected to the printed circuit board 12. The optical module also includes a heat pipe 16 disposed between the housing 10 and the heat generating chip 14. The heat pipe 16 has a heat absorbing end 18 abutting the heat generating chip 14 and a heat dissipating end 20 away from the heat generating chip 14. Thus, the heat absorbing end 18 absorbs heat generated from the heat generating chip 14 and transfers the heat to the heat dissipating end 20, which then transfers the heat to an area of the housing 10 that is away from the heat generating chip 14. The optical module further includes an optical interface and an electrical interface. A peripheral electrical interface is disposed on the printed circuit board 12 for realizing external electrical connection.

Table 1 shows a detailed comparison between the heat dissipation of the embodiment of the present disclosure and the heat dissipation of currently available technology:

TABLE 1

| | Temperature | |
|---|---|---|
| | Currently Available | |
| Location | Technology | Present Disclosure |
| Area of housing near chip | 54.8° C. | 46.2° C. |
| Area of housing farthest | 32.6° C. | 44.2° C. |
| away from chip | | |
| Chip junction area | 61.4 | 56.5 |

As Table 1 clearly shows, in the currently available technology, the temperature difference between the area of the housing 10 near the chip 14 and the area of the housing 10 farthest away from the chip 14 is 54.8−32.6=22.2° C. In the embodiment of the present disclosure, the temperature difference between the area of the housing 10 near the chip 14 and the area of the housing 10 farthest away from the chip 14 is 46.2−44.2=2° C. In the embodiment of the present disclosure, the temperature difference between the area of the housing 10 near the chip 14 and the area of the housing 10 farthest away from the chip 14 is reduced significantly from 22.2° C. to 2° C. Additionally, the embodiment of the present disclosure reduces the temperature of the area of the housing 10 near the chip 14 from 54.8° C. to 46.2° C., resulting in a total reduction of 54.8−46.2=8.6° C. Moreover, the embodiment of the present disclosure reduces the temperature of the area of the housing 10 near the chip 14 from 61.4° C. to 56.5° C., resulting in a total reduction of 61.4−56.5=4.9° C.

According to Table 1 and the analysis above, in the embodiment of present disclosure, by means of the heat pipe 16 disposed between the housing 10 and the heat generating chip 14, the heat absorbing end 18 absorbs the heat generated from the heat generating chip 14 and transfers the heat to the heat dissipating end 20, which then transfers the heat to the area of the housing 10 away from the heat generating chip 14. This, in turn, reduces the operating junction temperature of the heat generating chip 14 and allows the temperature of the housing 10 to be more uniform, thereby significantly increasing the service life of the optical module 100.

In the embodiment of the present disclosure, the housing 10 includes an upper housing 22 and a lower housing 24 connected to the upper housing 22. The upper housing 22 and the lower housing 24 form an accommodating cavity. At least part of the printed circuit board 12 is in the accommodating cavity. The heat generating chip 14 and the heat pipe 16 are both in the accommodating cavity. The heat generating chip 14 and the heat pipe 16 are located between the printed circuit board 12 and the lower housing 24. The heat generating chip 14 is disposed on the printed circuit board 12. The heat pipe 16 is disposed on the lower housing 24. The upper housing 22 and the lower housing 24 may be secured together by means of screws. Other securing means may also be used between the upper housing 22 and the lower housing 24.

In an exemplary embodiment, the heat pipe 16 is soldered or adhesively bonded to the housing 10. Alternatively, other securing means may also be used to secure the heat pipe 16 to the housing 10.

The heat generating chip 14 may be configured as an optical chip, electrical chip, etc. When the heat generating chip 14 is configured as an optical chip, the heat generating chip 14 may be configured as a transmitting-end chip set or a receiving-end chip set. For example, the heat generating chip 14 may be configured as a laser or a photoelectric detector. When the heat generating chip 14 is configured as a laser or a photoelectric detector, it may also have other components such as a driver or an optoelectronic signal sensor. Better heat dissipation is realized when the heat generating chip 14, which is a high heat-producing component, is disposed immediately next to the heat pipe 16. When the heat generating chip 14 is configured as an electrical chip, it may be specifically configured as a signal processing chip, a control chip, etc.

Additionally, in the present exemplary embodiment, the heat generating chip 14 is disposed close to one end rather than in the middle of the printed circuit board 12. This design facilitates the design of the optical path and the assembly of components. The optical module may further include a heat sink (not shown in the figure). In this case, the heat generating chip 14 is disposed on the heat sink rather than the printed circuit board 12. The heat sink and the housing 10 are thermally connected, the heat pipe 16 is disposed on one side of the heat sink, and the heat pipe 16 is thermally connected to the heat sink and the housing 10.

The heat pipe 16 is disposed close to the lower housing 24. Therefore, heat generated by the heat generating chip 14 is primarily transferred to the lower housing 24. The lower housing 24 has a special heat dissipating design to dissipate heat out of the housing 10 more effectively.

In the present exemplary embodiment, the printed circuit board 12 is secured to the housing 10 through an engagement structure. Alternatively, other connecting means may also be used to dispose the printed circuit board 12 within the housing 10. Further, a raised platform 25 is disposed within the housing 10 to support the printed circuit board 12. The raised platform 25 and the heat pipe 16 are disposed on the same side of the printed circuit board 12.

The heat pipe 16 includes a casing, a wick, a vapor cavity, and working fluid. The casing is a pressure-bearing component made of material featuring high thermal conductivity, puncture resistance, and thermal stress resistance. The material of the casing is usually stainless steel, copper, aluminum, nickel, etc. The function of the casing is to enclose the working portion of the heat pipe 16, receive heat from the heat absorbing end 18, release heat to the heat dissipating end 20, and bear a pressure difference when the pressure inside the pipe 16 is different from the pressure outside the pipe 16. The wick is a capillary structure immediately next to the inner wall of the casing. The working fluid has a relatively high latent heat of vaporization and thermal conductivity coefficient, suitable saturation pressure and boiling point, relatively low viscosity, and good stability.

The heat generating chip 14 has a first surface facing toward the printed circuit board 12 and a second surface facing away from the first surface. The heat pipe 16 is a planar heat pipe. The heat absorbing end 18 of the heat pipe 16 has a contact plane that contacts the second surface of the heat generating chip 14.

Further, a supporting plate 26 is disposed between the housing 10 and the heat pipe 16. In the present exemplary embodiment, the material of the supporting plate 26 is copper. Alternatively, the supporting plate 26 may be made of another material featuring a high thermal conductivity coefficient.

Further, the supporting plate 26 has a first end portion 28 near the heat generating chip 14 and a second end portion 30 disposed opposite the first end portion 28. The second end portion 30 is relatively far away from the heat generating chip 14 compared to the first end portion 28, and is in a direction parallel to the contact plane of the heat pipe 16. An area of the first end portion 28 is larger than an area of the second end portion 30. This design increases a heat absorbing area and facilitates heat dissipation. Specifically, the first end portion 28 is configured in a fan shape.

Additionally, at least a portion of the supporting plate 26 extends beyond the heat pipe 16 in the direction parallel to the contact plane of the heat pipe 16. Such configuration facilitates a secure connection between the heat pipe 16 and the supporting plate 26 and provides more stable support. In the present exemplary embodiment, the heat pipe 16 is soldered or adhesively bonded to the supporting plate 26. Alternatively, other connecting means may also be used between the heat pipe 16 and the supporting plate 26.

Additionally, there may be a plurality of the heat generating chips 14. In this case, the heat absorbing end 18 of the heat pipe 16 is disposed near to the center of the plurality of heat generating chips 14. In this manner, the heat absorbing end 18 absorbs the heat generated from the plurality of heat generating chips 14 and transfers the heat to the heat dissipating end 20, which eventually transfers the heat to the area of the housing 10 relatively far away from the plurality of heat generating chips 14, thereby allowing the temperature of the housing 10 to be uniform and increasing the service life of the optical module 100. Specifically, the plurality of heat generating chips 14 may be configured as identical chips or different chips.

In comparison with the currently available technology, the embodiments of the present disclosure provide the benefits described below. In the technical solution provided by the present disclosure, the heat pipe 16 is disposed between the housing 10 and the heat generating chip 14. The heat pipe 16 has the heat absorbing end 18 abutting the heat generating chip 14 and the heat dissipating end 20 away from the heat generating chip 14. The heat absorbing end 18 absorbs the heat generated from the heat generating chip 14 and transfers the heat to the heat dissipating end 20, which then transfers the heat to the area of the housing 10 that is away from the heat generating chip 14, thereby reducing the operating junction temperature of the heat generating chip 14, allowing the temperature of the housing 10 to be more uniform. As a result, the service life of the optical module 100 can be increased significantly.

It should be understood that despite the descriptions of embodiments in the specification, each embodiment does not entail only one independent technical solution. The specification is written this way simply for the sake of clarity. Persons having ordinary skill in the art should treat the specification as a whole. The technical solutions in the embodiments may be combined in appropriate ways to form other embodiments that may be understood by persons having ordinary skill in the art.

The series of detailed descriptions above is only intended to provide specific descriptions of feasible embodiments of the present disclosure. The detailed descriptions are not to be construed as limiting the scope of protection for the present disclosure. All equivalent embodiments or changes that are not detached from the techniques of the present disclosure in essence should fall under the scope of protection of the present invention.

What is claimed is:

1. An optical module, comprising:
a housing;
a printed circuit board disposed in the housing;
a heat generating chip electrically connected to the printed circuit board; and
a heat pipe disposed between the housing and the heat generating chip, the heat pipe having a heat absorbing end abutting the heat generating chip and a heat dissipating end away from the heat generating chip,
wherein the heat absorbing end absorbs heat generated from the heat generating chip and transfer the heat to the heat dissipating end, and the heat dissipating end transfers the heat to an area of the housing that is away from the heat generating chip.

2. The optical module of claim 1, wherein the heat generating chip has a first surface facing toward the printed circuit board and a second surface facing away from the first surface,
the heat pipe being a planar heat pipe, and
the heat absorbing end of the heat pipe having a contact plane that contacts the second surface of the heat generating chip.

3. The optical module of claim 2, further comprising a supporting plate disposed between the housing and the heat pipe.

4. The optical module of claim 3, wherein a material of the supporting plate is copper.

5. The optical module of claim 3, wherein the supporting plate has a first end portion near the heat generating chip and a second end portion disposed opposite the first end portion,
the second end portion being relatively far away from the heat generating chip compared to the first end portion, and being in a direction parallel to the contact plane, and
an area of the first end portion being larger than an area of the second end portion.

6. The optical module of claim 3, wherein at least a portion of the supporting plate extends beyond the heat pipe in a direction parallel to the contact plane.

7. The optical module of claim 3, wherein the heat pipe is soldered or adhesively bonded onto the supporting plate.

8. The optical module of claim 1, wherein the heat pipe is soldered or adhesively bonded onto the housing.

9. The optical module of claim 1, further comprising a raised platform disposed within the housing to support the printed circuit board, the raised platform and the heat pipe being disposed on the same side of the printed circuit board.

10. The optical module of claim 1, wherein there are a plurality of the heat generating chips, the heat absorbing end of the heat pipe being disposed near the center of the plurality of heat generating chips to absorb the heat generated from the plurality of heat generating chips and transfer the heat to the heat dissipating end.
